(19) United States
(12) Patent Application Publication
(10) Pub. No.: US 2026/0331355 A1
(43) Pub. Date: Oct. 22, 2026

(54) Arrangement and Method for Forming an Arrangement

(71) Applicant: Intel Corporation, Santa Clara, CA (US)

(72) Inventors: Casey THIELEN, Chandler, AZ (US); Shamsul ABEDIN, Portland, OR (US); Zhen ZHOU, Chandler, AZ (US)

(21) Appl. No.: 19/428,481

(22) Filed: Dec. 22, 2025

Related U.S. Application Data
(60) Provisional application No. 63/917,521, filed on Nov. 14, 2025.

(51) Int. Cl. H01F 27/28; H10W 20/40

(52) U.S. Cl. CPC H01F 27/2804; H10W 20/497

(57) ABSTRACT

Various examples relate to an arrangement and to a method for forming an arrangement. The arrangement comprises a first component comprising a surface region with a first plurality of inductive elements for interfacing with a second plurality of inductive elements of a second component, and a filler material arranged on the surface region comprising the first plurality of inductive elements, so that, when the second component is arranged on the filler material, the filler material is arranged between the first and second plurality of inductive elements, wherein the filler material comprises nanoparticles configured to increase a magnetic permeability of the filler material.

### CROSS-REFERENCE TO RELATED APPLICATION

This application claims the benefit of priority under 35 U.S.C. § 119(e) to U.S. Provisional Application No. 63/917,521, filed on Nov. 14, 2025, the entire contents of which are hereby incorporated by reference.

### BACKGROUND

On-package memory places DRAM (Dynamic Random Access Memory) or SRAM (Static Random Access Memory) within the same package as the processor, often as stacked high-bandwidth memory (HBM) connected through a silicon interposer or embedded bridge. This shortens interconnect distance, delivering very high bandwidth, lower latency and lower energy per bit compared to socketed DIMMs (Dual In-Line Memory Module), while simplifying board routing. It is common in GPUs (Graphics Processing Units) and AI (Artificial Intelligence) accelerators and also appears in some CPUs (Central Processing Units) for bandwidth-intensive workloads. The trade-offs include higher cost per gigabyte, limited capacity relative to off-package memory, and tighter thermal constraints.

3D stacking puts memory dies directly above a logic die, bonded with through-silicon vias, micro-bumps, or hybrid bonding so that signals travel microns instead of centimeters. Stacked SRAM caches and DRAM-on-logic prototypes show substantial bandwidth and latency gains from dense vertical connections, enabling larger effective caches and near-memory bandwidth without extremely wide external buses. The main challenges are heat removal through the stack, yield, test complexity, repairability, and clean power delivery to upper layers. Consequently, many designs stack small, fast SRAM caches and place larger DRAM stacks nearby on the package to balance performance, capacity, and thermal limits.

Microelectronic connections typically rely on solder bumps, Cu-pillars or other direct electrical connections between silicon-based electronic components such as compute chips and silicon interposers (either active or passive). Other direct-electrical connections can involve sockets with pins or pads that physically touch an electrical pad on a substrate or PCB (Printed Circuit Board). These sockets can take many forms and have been extensively used across the electronics industry in various applications. Their minimum pitch varies, depending on the socket technology used, but generally does not go below 0.3 mm and is typically not much below 1 mm. There are various other non-contact options that could include light, sound, or other energy-based waves as well. These have reached various stages of development but have seen very limited use in any end-product.

### BRIEF DESCRIPTION OF THE FIGURES

Some examples of apparatuses and/or methods will be described in the following by way of example only, and with reference to the accompanying figures, in which:

FIG. 1 shows an illustration of top and bottom components prior to the top component landing on the bottom component, each with inductive arrays;

FIG. 2 shows an illustration of an elastomeric material filled with high permeability nanoparticles dispensed onto one or both facing surfaces of the components prior to the top component being seated on the bottom component;

FIG. 3a shows two inductive coil arrays lined up opposite each other;

FIG. 3b shows two components with inductive coil arrays arranged on top of each other;

FIG. 3c shows a stack comprising a filler material between two components;

FIG. 4 shows a side view of the two components after the top component is seated on the bottom component;

FIG. 5 shows a flowchart of a method for forming an arrangement;

FIG. 6a shows an example of filler material applied to a surface in a serpentine pattern;

FIG. 6b shows an example of drops of filler material applied to a surface;

FIG. 6c shows an example of drops of filler material with different configurations of nanoparticles applied to a surface;

FIG. 6d shows an example of a top view of drops of filler material with different configurations of nanoparticles applied to a surface;

FIG. 6e shows an example of a planar sheet of filler material with different configurations of nanoparticles;

FIG. 6f shows another example of a planar sheet of filler material with different configurations of nanoparticles;

FIGS. 7a and 7b show a 3D visual comparison of the send-receive inductors; and

FIG. 8 shows the improvement by using an elastomeric filler with a frequency-tuned permeability of 4.

### DETAILED DESCRIPTION

Some examples are now described in more detail with reference to the enclosed figures. However, other possible examples are not limited to the features of these embodiments described in detail. Other examples may include modifications of the features, as well as equivalents and alternatives to the features. Furthermore, the terminology used herein to describe certain examples should not be restrictive of further possible examples.

Throughout the description of the figures, same or similar reference numerals refer to the same or similar elements and/or features, which may be identical or implemented in a modified form while providing the same or a similar function. The thickness of lines, layers, and/or areas in the figures may also be exaggerated for clarification.

When two elements A and B are combined using an “or”, this is to be understood as disclosing all possible combinations, i.e., only A, only B, as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an”, or “the”, is used and the use of only a single element is not defined as mandatory, either explicitly or implicitly, further examples may also use several elements to implement the same function. If a function is described below as being implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Various examples of the present disclosure relate to a high permeability filled elastomer for inductor-based communications between electronic components.

New memory-based technology is being developed, and one potential option for enabling communication between electronic devices is to use inductive elements that transfer signals across very short distances (e.g., 5-50 μm spacing, or more). Using this technology provides the ability to place memory on the package after the traditional assembly process and after the packaged part has been shipped to the customer. This “socket-like” solution allows placement of memory by the customer/end-user without having to buy the memory from the company that designed and assembled the packaged-part. It also provides the option of determining the amount of memory prior to shipping the part to the ultimate end-user. Any yield issues may be easily solved with the easy removal and replacement of the memory using this method.

While this is specifically applied to late-attached memory on the packaged product, it can be applied to other situations where late attach onto a product provides distinct value, such as a compute product onto a board, interposer, or other platform that allows attaching just before shipping to the end-customer.

Recently, inductive elements have been explored as alternatives to solder-based connections for certain applications that may benefit from a non-physical connection that enables removability/replaceability. This is often referred to as a “late-attach” option for an electronic product. Depending on the size of the inductor pad and the power used to send the signal, the distance to the receiving inductor pad can be extremely short and may limit practical application of this technology.

Various examples of the present disclosure are based on the finding that inductive coupling between components, such as semiconductor dies, package substrates, printed circuit boards, or interposers, faces significant challenges related to signal quality and coupling efficiency. When inductive elements on separate components are used for data transmission, the gap between these components introduces a region with low magnetic permeability, which reduces the magnetic flux linkage between the inductive elements and thereby diminishes the efficiency of signal transfer. This technical problem becomes particularly pronounced at high frequencies used in modern data transmission applications, where maintaining strong magnetic coupling is essential for reliable communication between components.

To extend the reach of this communication interface between two components, a medium is proposed to fill the airgap between the inductor “send and receive” pads to improve signal loss. The present disclosure relates to a technique for enhancing magnetic coupling between inductive elements of separate components by introducing a filler material with application-tailored magnetic permeability into the gap between the components. The proposed concept addresses the challenges of using short-distance connections by incorporating nanoparticles within the filler material that are specifically configured to increase the magnetic permeability of the filler material. By positioning this enhanced filler material between a first and second plurality of inductive elements, the magnetic flux path between the inductive elements is improved, resulting in stronger magnetic coupling and more efficient signal transmission. This improves the overall performance of inductive data links between components and enables more reliable high-frequency communication. In some examples, the proposed concept involves filling an elastomer interposer with a high permeability material such as yttrium iron garnet (YIG), Cobalt ferrite, or Manganese-Zinc ferrite (or other) nanoparticles. This elastomeric material can be dispensed onto the pad-array surface and squeezed down to the desired thickness when mounting/seating the component to the inductive interposer.

The filler material between the inductor pads may replace the airgap with a high permeability material that enhances the signal propagation between the pads, allowing either larger spacing (gap-height) at the same power per bit or reduced power per bit at an equivalent gap-height, or a combination of the two. Additionally, using nanoparticles in an insulated material greatly reduces eddy currents and provides a better path to maintaining high permeability of that material. In fact, recent studies indicate nanoparticles in a dielectric medium show significantly high permeability in the GHz region, with the ability to tune this depending on particle size and shape, material used, and spacing between nanoparticles. Simulation results indicate this may improve signal crosstalk between nearby inductive elements, which may improve the overall channel loss margin of the system for a given size and pitch of an inductor pad array. Use of an elastomeric material also provides mechanical protection to the inductive elements by maintaining a gap between the two interfaces vs allowing intimate contact, which could result in mechanical failure on either side since silicon-based electronic components are being used. This is especially important if the surfaces on either side's topology is not uniformly flat but instead contains peaks and valleys that would be the source of local stress concentrations (stress-risers) when pressed together. Using a flexible material such as an elastomer allows the high permeability material to be shaped uniquely for each part using appropriate mechanical pressure, thereby avoiding the need for additional tolerancing of a rigid material such as a chiplet, spacer or thin film. This in turn may optimize/minimize gap spacing between transceiver pads.

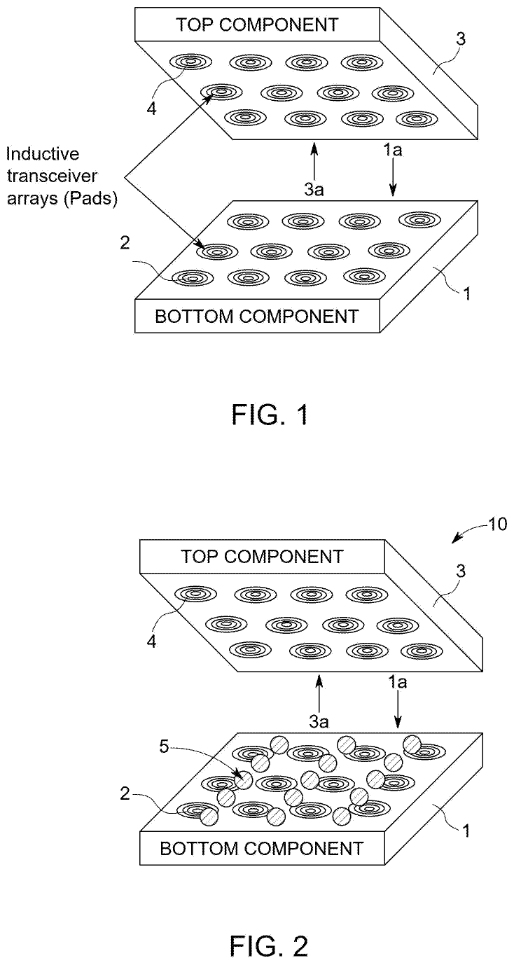

FIG. 1 shows an illustration of a top component 3 and a bottom component 4 prior to the top component 3 landing on the bottom component 4. The top component (also denoted second component 3 in the following) has a plurality of inductive elements 4 (e.g., inductive antennas, inductive pads, inductive plates, inductive strips etc.), and the bottom component (also denoted first component 1 in the following) has a plurality of inductive elements 2 (e.g., inductive antennas, inductive pads, inductive plates, inductive strips etc.). The respective pluralities of inductive elements may be arranged as inductive arrays, with the two pluralities of inductive elements/inductive arrays lined up opposite each other.

FIG. 2 shows an illustration of an (elastomeric) filler material filled with high-permeability nanoparticles dispensed onto one or both facing surfaces 1a, 3a of the components prior to the top component being seated on the bottom component. The present disclosure thus provides an arrangement comprising the first component 1 comprising a surface region 1a with the first plurality of inductive elements 2 for interfacing with the second plurality of inductive elements 4 of the second component 3. The arrangement further comprises the filler material 5 arranged on the surface region 1a comprising the first plurality of inductive elements 2, so that, when the second component 3 is arranged on the filler material 5, the filler material is arranged between the first and second plurality of inductive elements 2, 4. As the filler material is arranged between the two components, it may also be denoted an “interposer” (not to be confused with the interposer 1 being used as first component in some of the figures). In some examples, the arrangement further comprises the second component 3, thus forming a component stack with the first component 1 and the filler material 5. The filler material 5 comprises nanoparticles configured to increase the magnetic permeability of the filler material. By incorporating nanoparticles that increase the magnetic permeability of the filler material, the magnetic coupling between the first and second plurality of inductive elements is enhanced, resulting in improved signal transmission efficiency and reduced signal loss.

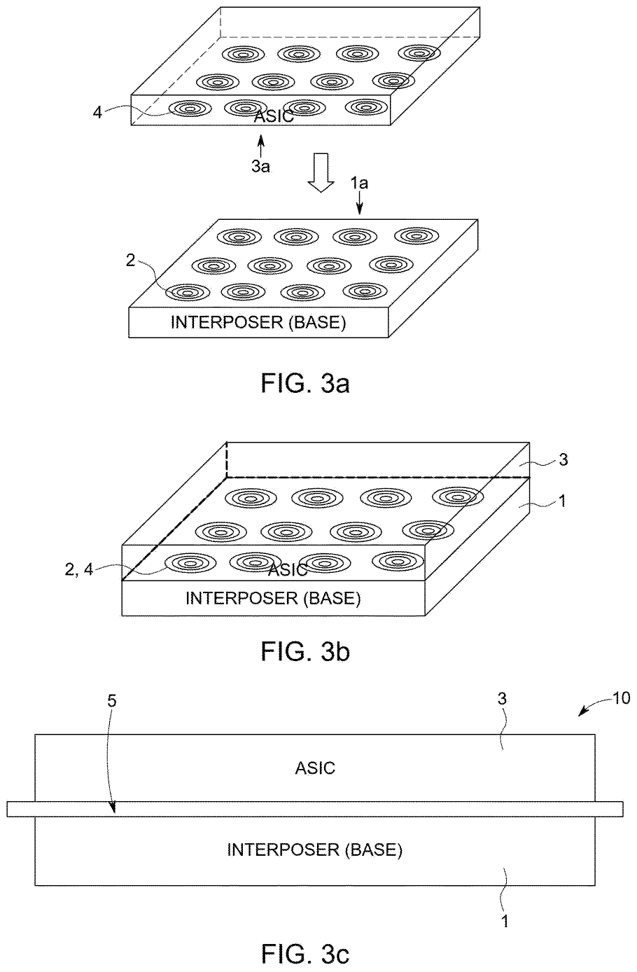

The purpose of the filler material is to improve the signal transmission properties between inductive elements 4 and 2 on either side of the filler material. Therefore, the respective inductive elements are placed opposite each other. FIG. 3a shows two inductive coil arrays 2 and 4 lined up opposite each other (with a first component 1 that is an interposer/base and a second component 3 that is an Application Specific Integrated Circuit (ASIC), i.e., a semiconductor die). In FIG. 3b, the two components 1 and 3 are shown with the inductive coil arrays arranged on top of each other. The ASIC 3 is placed on top of the interposer/base 1 so that the inductive coils are at a minimum distance apart. The high-permeability material in between the ASIC 3 and base 1 is not shown in this visualization. FIG. 3c shows a front view of a stack comprising the filler material 5 between the two components 1 and 3. It shows a close-up with a nanoparticle-filled filler material (e.g., elastomer filler material) between ASIC 3 and interposer 1. The filler material, which may be a flexible compound (elastomer), can be dispensable (e.g., using a syringe, as shown in FIG. 2). It can also be a pre-form which maintains a deformable property.

In the proposed concept, a filler material is used. In the context of the present disclosure, the filler material 5 is a material that is arranged between the first component 1 and the second component 3. When in use, the filler material may provide a planar surface towards at least one of the surfaces 1a, 3a of the two components. In various examples, this filler material is an elastomeric filler material. An elastomeric material, or elastomer, is a polymer material that exhibits elastic properties, meaning it can undergo significant deformation under mechanical stress and return substantially to its original shape when the stress is removed. In the context of this disclosure, an elastomer-such as silicone elastomers, polyurethane elastomers, fluoroelastomers, or thermoplastic elastomers-serves as the base matrix material of the filler in which high-permeability nanoparticles are dispersed. The elastomer can be dispensed onto a component surface in a flowable state and then compressed to a desired thickness when the mating component is mounted, allowing the material to conform to surface irregularities and variations in component flatness without requiring precise pre-formed tolerances. This conformability ensures consistent gap spacing between inductive elements even when component surfaces contain peaks and valleys that would otherwise create stress concentrations. Additionally, the elastomeric filler provides mechanical protection by maintaining a controlled gap between the two component interfaces, preventing direct contact that could cause mechanical failure of silicon-based electronic components. On the other hand, the elastomeric properties may not be relevant to the purpose of improving the properties of the inductive signal transmission. Therefore, the proposed concept involves the creation of an elastomeric or non-elastomeric filler material (to be used as interposer between the components, e.g., between a base/interposer and a die) that is infused with nanoparticles of high permeability material(s).

To accommodate typical component spacing and assembly tolerances while maintaining effective coupling, the filler material thickness should be appropriately dimensioned. In some examples, the filler material may have a vertical thickness between 5 μm and 100 μm. This thickness range provides sufficient mechanical separation between components while ensuring that the enhanced magnetic permeability effectively bridges the gap between the inductive elements.

The filler material is filled with nanoparticles, which are used to control the magnetic permeability of the filler material. Nanoparticles are particles of matter with dimensions typically ranging from 1 to 100 nanometers (nm), where at least one dimension falls within this nanoscale range. In the context of the present disclosure, nanoparticles refer to particles of high magnetic permeability materials—such as yttrium iron garnet (YIG), Cobalt ferrite, Manganese-Zinc ferrite, Iron ferrite, Nickel ferrite, Z-type hexagonal ferrite, or Cobalt Iron Boron alloy—that are dispersed within the filler material to enhance its magnetic properties. In other words, the nanoparticles may comprise at least one of yttrium iron garnet (YIG), Iron ferrite, Nickel ferrite, a Z-type hexagonal ferrite, Cobalt ferrite, Manganese-Zinc ferrite, or a Cobalt Iron Boron alloy. The use of nanoparticles provides significant advantages over bulk magnetic materials because at nanoscale dimensions, the particles exhibit reduced eddy current losses since the particle size is smaller than the skin depth at high frequencies. This allows the material to maintain high magnetic permeability even in the GHz frequency range. Furthermore, nanoparticles embedded in a dielectric medium can be engineered to exhibit magnon resonance at specific target frequencies, enabling frequency-tuned permeability enhancement. The size, shape, material composition, and spacing of the nanoparticles can be adjusted to optimize the magnetic permeability for the specific operating frequency of the inductive data link.

To achieve a meaningful improvement in magnetic coupling performance, the magnetic permeability of the filler material should exceed certain threshold values. For example, the nanoparticles may be configured to increase the relative magnetic permeability of the filler material to at least μr=2 at a target frequency. By achieving a relative magnetic permeability of at least 2, a significant enhancement in magnetic flux concentration between the inductive elements is obtained, thereby improving coupling efficiency. In some examples, the nanoparticles may be configured to increase the relative magnetic permeability of the filler material to at least μr=3 or at least μr=4 at a target frequency. These higher permeability values further concentrate the magnetic field between the inductive elements, enabling superior signal transfer performance and potentially allowing for reduced pad sizes or increased pad spacing while maintaining adequate coupling.

Depending on the signal frequency with which the inductive elements send a signal, the nanoparticles in the elastomer may be engineered to support a targeted frequency. For example, the aforementioned target frequency may be a frequency used for data transmission between the first and second plurality of inductive elements. In particular, the target frequency may be between 2 GHz and 20 GHz (e.g., between 5 GHz and 10 GHz), which encompasses frequencies commonly used for high-speed data transmission. By improving the magnetic permeability at the actual data transmission frequency, the proposed concept ensures that the coupling enhancement is realized during normal operation of the arrangement. At GHz frequencies (being used for data transmission), standard ferromagnetic properties have greatly diminished due to eddy currents and Ferromagnetic Resonances (FMR), so engineered materials may be used to target magnon resonance, which is frequency-specific and drops off quickly outside of that tight frequency range. Examples of materials with magnon resonance in the 5-10 GHz range have been shown to have the ability to engineer for targeted frequencies. Specifically, nanoparticles in a dielectric medium have shown very good permeability values (up to 10 H/m for both the real and imaginary parts) in the 1-20 GHz range.

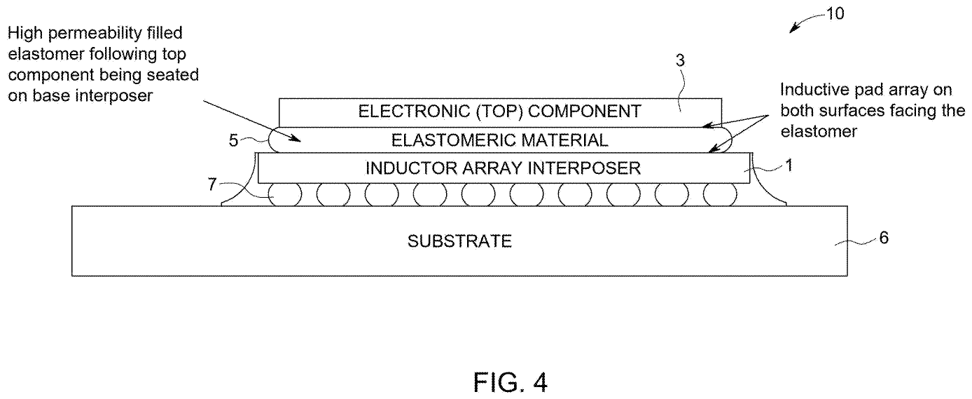

FIG. 4 shows a side view of the two components 1 and 3 after the top component 3 (an electronic component) is seated on the bottom component 2 (an inductor array interposer). FIG. 4 shows an example of these components 1 and 3 being attached to a substrate 6 via a ball grid array 7.

In general, the proposed concept can be used with various types of components used in electronic assemblies. For example, the first component 1 and/or the second component 3 may be a semiconductor die, such as a processor die or memory die. By integrating the enhanced filler material with a semiconductor die, high-speed inductive communication can be established directly from the die surface. For example, the first component 1 and/or the second component 3 may be a printed circuit board (PCB). This configuration enables inductive coupling between a printed circuit board and other components, providing a contactless interface that may simplify assembly and improve reliability. For example, the first component 1 and/or the second component 3 may be a package substrate. A package substrate equipped with inductive elements and the enhanced filler material can establish efficient inductive links to dies or other substrates (such as a PCB) within a packaged assembly. Finally, as shown in FIG. 4, the first component 1 and/or the second component 3 may be an interposer. An interposer with inductive elements and the enhanced filler material can serve as an intermediate layer facilitating high-speed inductive communication between multiple components in a stacked or side-by-side arrangement.

Visual inspection may reveal the film, especially in the presence of inductive element arrays. Additional testing of the film may indicate the composition of high-permeability materials such as manganese-zinc ferrite, cobalt ferrite, nickel ferrite, or iron ferrite, and many other options, depending on the desired frequency and other factors such as the supportability of metamaterial creation.

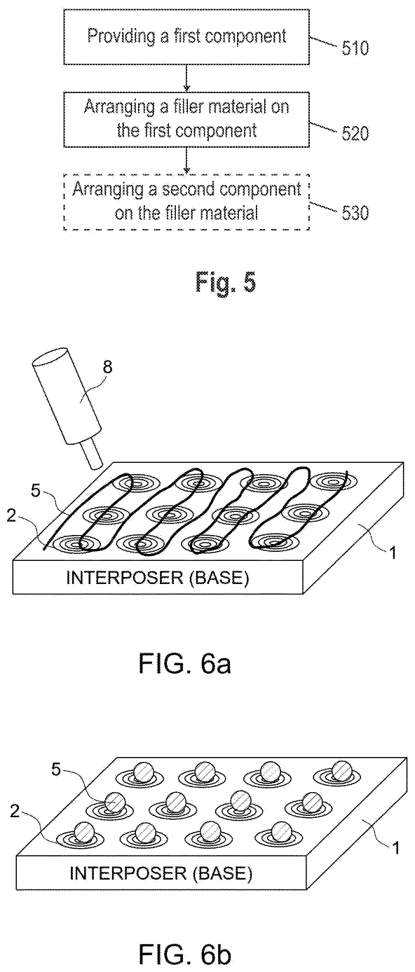

More details and aspects of the arrangement 10 (e.g., of the filler material 5) are mentioned in connection with the proposed concept, or one or more examples described above or below (e.g., FIGS. 5 to 8). The arrangement 10 (e.g., the filler material 5) may comprise one or more additional optional features corresponding to one or more aspects of the proposed concept, or one or more examples described above or below.

FIG. 5 shows a flowchart of a method for forming an arrangement, such as the arrangement 10 of FIGS. 1 to 4. The method comprises providing 510 a first component comprising a surface region with a first plurality of inductive elements for interfacing with a second plurality of inductive elements of a second component. The method further comprises arranging 520 a filler material on the surface region comprising the first plurality of inductive elements, so that, when the second component is arranged on the filler material, the filler material is arranged between the first and second plurality of inductive elements. The filler material comprises nanoparticles configured to increase a magnetic permeability of the filler material. By this method, an arrangement with enhanced magnetic coupling between inductive elements can be efficiently manufactured, resulting in improved signal transmission performance.

To complete the formation of the inductive coupling arrangement, the second component may be added. Accordingly, the method may further comprise arranging 530 the second component on the filler material. Arranging the second component (as well as arranging the filler material) does not have to be performed at the time of manufacturing the first component. In particular, the proposed concept may be applied to install the second component after packaging. For example, to enable flexible manufacturing processes and late-stage customization, the second component may be arranged on the filler material after packaging (of the first component). This allows the first component to be fully packaged before the second component is mounted, enabling modular assembly approaches and facilitating testing before final assembly.

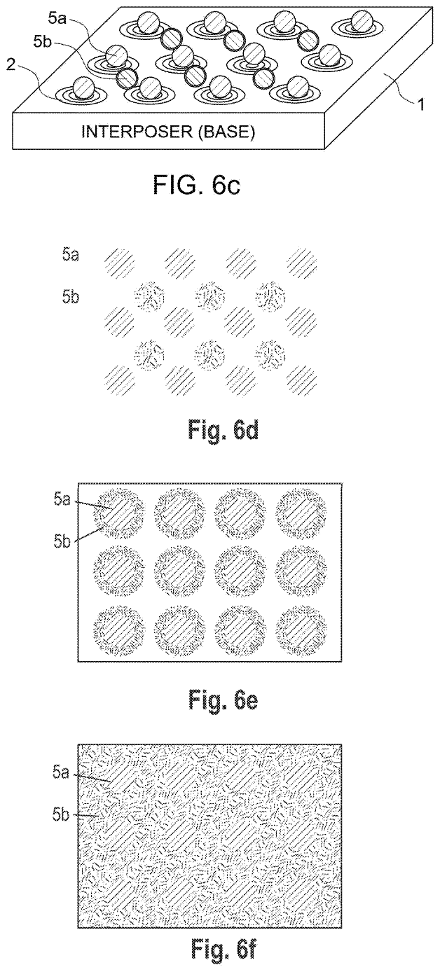

There are two main variants for arranging the filler material on the first component. In the first variant, shown in FIGS. 2 and 6a-6d, the filler material is applied in liquid or semi-liquid form.

For instance, the nanoparticle-infused elastomer can be dispensed onto the planar surface 1a—or even a nonuniform surface-along with the array of planar inductor pads 2. To simplify the deposition process and ensure proper coverage of the surface region, the filler material may be applied using a droplet-based approach. In this method, the filler material is deposited as droplets on the first component. This provides a deposition method wherein the nanoparticle-containing filler material is dispensed onto a component surface in the form of discrete liquid or semi-liquid droplets, which are subsequently spread and distributed across the surface region by mechanical pressure exerted during mounting of the mating component. The droplet-based application may be performed using precision dispensing equipment or jetting techniques to deposit filler material droplets onto specific locations corresponding to inductive element positions. In an alternative example, the filler material may be applied as a continuous flow in a serpentine pattern across the surface region, wherein the dispensing path follows a continuous back-and-forth trajectory that ensures comprehensive coverage of the inductive element array while optimizing material distribution and minimizing void formation during compression. In both cases, the respective filler material—i.e., the droplets or the serpentine-pattern filler material—is deposited such that it is spread across the surface region by mechanical pressure exerted by the second component upon mounting of the second component. Both deposition approaches provide manufacturing flexibility and process simplification compared to pre-formed sheet materials, as precise control over the amount of material applied can be achieved. The mounting process itself serves to distribute the material uniformly across the inductive elements without requiring additional spreading or planarization steps. These methods are particularly advantageous for accommodating non-uniform surfaces, as the flowable filler material can conform to surface topology variations before being compressed to the final thickness. The deposition methods also enable selective application of filler material only to regions where it is needed, potentially reducing material usage and allowing for different filler compositions to be applied to different areas of the same component surface. FIGS. 6a and 6b illustrate the two methods. FIG. 6a shows an example of filler material 5 applied to the surface in a serpentine pattern, while FIG. 6b shows an example of droplets 5 of filler material applied to the surface.

The second main variant is to provide the filler material as a planar sheet. In other words, the filler material may be pre-formed (i.e., before it is placed on the first component/between the first and second component) as a planar sheet. A planar sheet configuration facilitates handling and precise placement of the filler material on the surface region of the first component, and ensures uniform coverage over the plurality of inductive elements. A planar sheet filler material is a pre-formed, substantially flat layer of filler material (either elastomeric or non-elastomeric) that contains dispersed nanoparticles configured to increase magnetic permeability, and that is designed to be placed between two components to fill the gap between their respective inductive element arrays. Providing the filler material as a planar sheet offers manufacturing and assembly advantages by enabling precise handling and placement of the filler material on the surface region of a component. The planar sheet configuration ensures uniform coverage over the plurality of inductive elements and facilitates consistent thickness control across the entire interface area.

In both variations, the elastomer/pre-form can be uniformly filled with nanoparticles. Alternatively, to improve the magnetic field distribution and potentially reduce unwanted electromagnetic interference between adjacent inductive elements, the filler material may be configured with regions of varying magnetic properties. In other words, the filler material may have selective areas of high nanoparticle concentration or high permeability between coils and low permeability in locations where coils are not located. For example, the filler material may comprise a first plurality of regions having a first magnetic permeability and at least one second region comprising a second magnetic permeability. The first plurality of regions may be arranged opposite the first plurality of inductive elements and the at least one second region may encircle the respective regions of the first plurality of regions. By spatially varying the magnetic permeability, the magnetic field can be concentrated in desired areas while being attenuated in others.

In general, the first magnetic permeability is supportive of the inductive transmissions between corresponding contact pads, while the first magnetic permeability may be used to reduce unwanted signal coupling (i.e., crosstalk). This can be done in different ways, for example, the first magnetic permeability may be greater than the second magnetic permeability (e.g., the relative magnetic permeability of the first regions may be at least 120% (or at least 150%, or at least 200%) of the relative magnetic permeability of the second region(s)). By providing higher permeability directly opposite the inductive elements, the magnetic field is preferentially channeled through these regions, enhancing coupling efficiency while the lower permeability surrounding regions reduce cross-talk between adjacent pads. Alternatively, or additionally, the second regions may be configured to absorb stray magnetic fields. For example, the second magnetic permeability may be a complex magnetic permeability having a real part and an imaginary part. A loss tangent of the second magnetic permeability, defined as the ratio of the imaginary part to the real part, may be greater than a loss tangent of the first magnetic permeability (e.g., at least 120%, or at least 150%, or at least 200% of the loss tangent of the first magnetic permeability). By providing higher magnetic losses in the regions surrounding the inductive elements, stray fields are absorbed rather than coupled to adjacent pads, thereby improving signal isolation.

The use of first and second regions with different magnetic permeability is supported by both the pre-form and droplet/serpentine-based manufacturing variants. FIG. 6c shows an example of droplets of filler material with different configurations of nanoparticles applied to a surface. In FIG. 6c, droplets 5a of filler material, which are arranged opposite the inductive elements, have the first magnetic permeability, while droplets 5b of filler material, which are arranged laterally between the inductive elements, have the second magnetic permeability. FIG. 6d shows a corresponding top view of droplets 5a, 5c of filler material with different configurations of nanoparticles applied to a surface.

In FIGS. 6e and 6f, two configurations are shown that are enabled by using a planar sheet filler material. FIGS. 6e and 6f show examples of planar sheets of filler material with different configurations of nanoparticles. As shown, the planar sheet may be configured with the first plurality of regions 5a having a first (higher, or lower loss tangent) magnetic permeability arranged opposite the inductive elements, and second regions with a second (lower, or higher loss tangent) magnetic permeability encircling the first regions, thereby concentrating magnetic flux through the inductive elements while reducing cross-talk between adjacent pads. In FIG. 6e, the second regions have an annular (ring-shaped) form encircling the first regions (the remainder of the planar sheet can have any other magnetic permeability), while, in FIG. 6f, the second region 5b takes up the entire remainder of the planar sheet. The planar sheet form factor also enables quality control inspection and testing of the filler material properties prior to assembly. Both elastomeric and non-elastomeric sheet materials may be employed depending on the mechanical compliance requirements of the specific application.

Regardless of manufacturing variant used, the surface of the filler material acts functionally as a “socket” for placing or seating an electronic component such as a 3D-die stack that has a corresponding array of inductor pads for coupling, or a single component that contains the inductor array. When placing this component on the inductor array socket, in case an elastomeric material is used, the elastomer is compressed between the two surfaces to fill the air gap to a specified thickness, effectively replacing low-permeability air with a much more magnetic-coupling-friendly (i.e., high permeability) material.

More details and aspects of the method and the arrangement 10 (e.g., of the filler material 5) are mentioned in connection with the proposed concept or one or more examples described above or below (e.g., FIGS. 5 to 8). The method and the arrangement 10 (e.g., the filler material 5) may comprise one or more additional optional features corresponding to one or more aspects of the proposed concept or one or more examples described above or below.

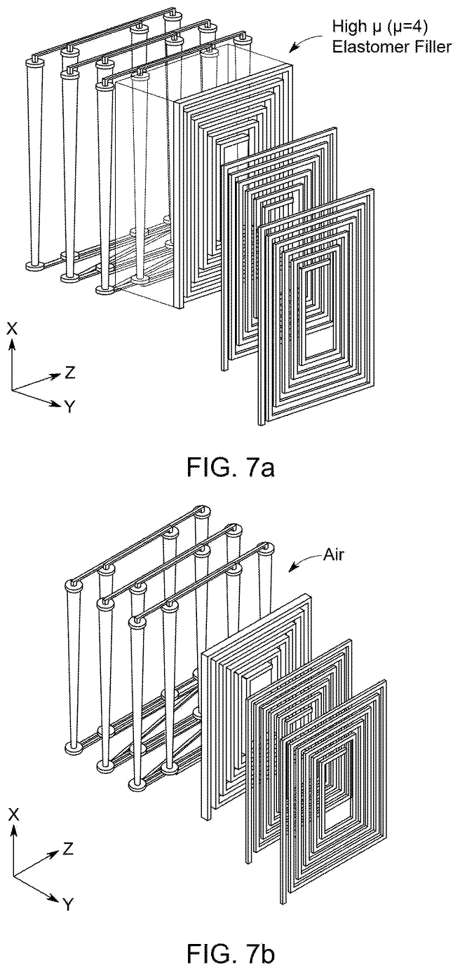

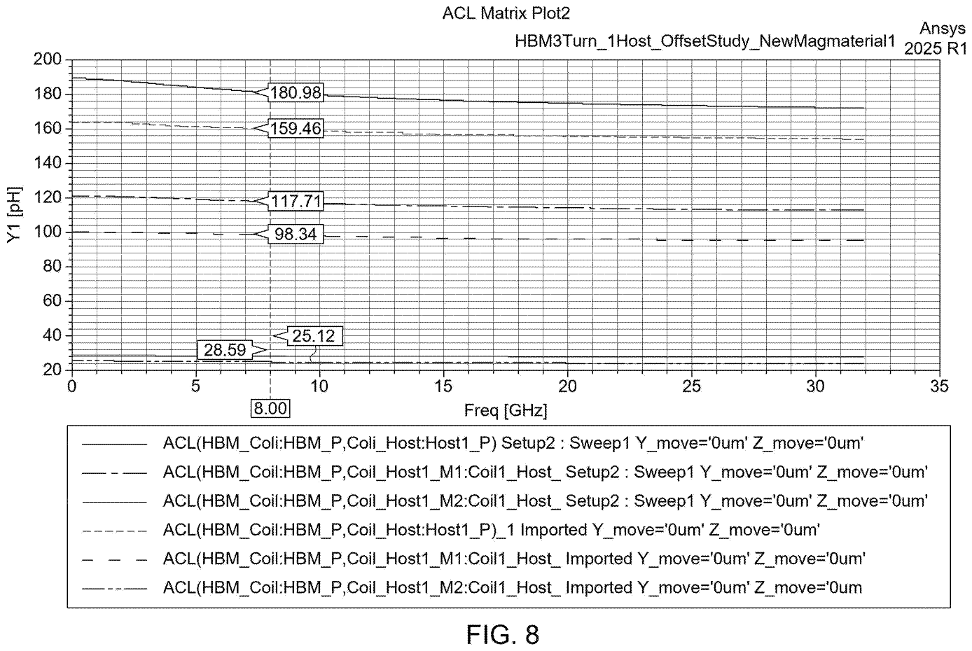

Simulation results indicate advantages in the signal loss budget between the send and receive inductors, using the setup shown in FIGS. 7a to 7b. FIGS. 7a and 7b show a 3D visual comparison of the send-receive inductors with either an air-gap (FIG. 7b) or a high-permeability filler (FIG. 7a) inserted between them (at a communication distance of 30 μm). FIG. 8 shows an illustration of the quantification of the improved signal loss budget for a direct comparison of the air-gap versus filler between inductors.

FIG. 8 shows the improvement achieved by using an elastomeric filler with a frequency-tuned permeability of 4. This improvement amounts to 13.5% for the large via-based multi-loop inductor and 19.7% for the in-plane multi-loop inductor. This comparison is carried out at a gap of 30 μm, as shown in FIGS. 7a and 7b. With the improved magnetic permeability, the gap can ideally increase by up to ~20%. This can provide a margin enhancement for component placement and/or signal fidelity.

In the following, some examples of the proposed concept are presented:

An example (e.g., example 1) relates to an arrangement (10), comprising a first component (1) comprising a surface region (1a) with a first plurality of inductive elements (2) for interfacing with a second plurality of inductive elements (4) of a second component (3), and a filler material (5) arranged on the surface region comprising the first plurality of inductive elements, so that, when the second component is arranged on the filler material, the filler material is arranged between the first and second plurality of inductive elements, wherein the filler material comprises nanoparticles configured to increase a magnetic permeability of the filler material.

Another example (e.g., example 2) relates to a previous example (e.g., example 1) or to any other example, further comprising that the nanoparticles are configured to increase the relative magnetic permeability of the filler material to at least μr=2 at a target frequency.

Another example (e.g., example 3) relates to a previous example (e.g., one of the examples 1 or 2) or to any other example, further comprising that the nanoparticles are configured to increase the relative magnetic permeability of the filler material to at least μr=3 or at least μr=4 at a target frequency.

Another example (e.g., example 4) relates to a previous example (e.g., one of the examples 2 or 3) or to any other example, further comprising that the target frequency is a frequency used for data transmission between the first and second plurality of inductive elements.

Another example (e.g., example 5) relates to a previous example (e.g., one of the examples 2 or 3) or to any other example, further comprising that the target frequency is between 2 GHz and 20 GHz.

Another example (e.g., example 6) relates to a previous example (e.g., one of the examples 1 to 5) or to any other example, further comprising that the filler material has a vertical thickness of between 5 μm and 100 μm.

Another example (e.g., example 7) relates to a previous example (e.g., one of the examples 1 to 6) or to any other example, further comprising that the nanoparticles comprise at least one of yttrium iron garnet (YIG), Iron ferrite, Nickel ferrite, a Z-type hexagonal ferrite, Cobalt ferrite, Manganese-Zinc ferrite, or a Cobalt Iron Boron alloy.

Another example (e.g., example 8) relates to a previous example (e.g., one of the examples 1 to 7) or to any other example, further comprising that the filler material is formed as a planar sheet.

Another example (e.g., example 9) relates to a previous example (e.g., one of the examples 1 to 8) or to any other example, further comprising that the filler material comprises a first plurality of regions (5a) having a first magnetic permeability and at least one second region (5b) comprising a second magnetic permeability, with the first plurality of regions arranged opposite the first plurality of inductive elements and the at least one second region encircling the respective regions of the first plurality of regions.

Another example (e.g., example 10) relates to a previous example (e.g., example 9) or to any other example, further comprising that the first magnetic permeability is greater than the second magnetic permeability.

Another example (e.g., example 11) relates to a previous example (e.g., example 9) or to any other example, further comprising that the second magnetic permeability is a complex magnetic permeability having a real part and an imaginary part, and wherein a loss tangent of the second magnetic permeability, defined as the ratio of the imaginary part to the real part, is greater than a loss tangent of the first magnetic permeability.

Another example (e.g., example 12) relates to a previous example (e.g., one of the examples 1 to 11) or to any other example, further comprising that the filler material is an elastomeric filler material.

Another example (e.g., example 13) relates to a previous example (e.g., one of the examples 1 to 12) or to any other example, further comprising that the first component is a semiconductor die, such as a processor die or memory die.

Another example (e.g., example 14) relates to a previous example (e.g., one of the examples 1 to 12) or to any other example, further comprising that the first component is a printed circuit board.

Another example (e.g., example 15) relates to a previous example (e.g., one of the examples 1 to 12) or to any other example, further comprising that the first component is a package substrate.

Another example (e.g., example 16) relates to a previous example (e.g., one of the examples 1 to 12) or to any other example, further comprising that the first component is an interposer.

Another example (e.g., example 17) relates to a previous example (e.g., one of the examples 1 to 16) or to any other example, further comprising that the arrangement further comprises the second component arranged on the filler material.

Another example (e.g., example 18) relates to a previous example (e.g., example 17) or to any other example, further comprising that the second component is a semiconductor die, such as a processor die or memory die.

Another example (e.g., example 19) relates to a previous example (e.g., example 17) or to any other example, further comprising that the second component is a printed circuit board.

Another example (e.g., example 20) relates to a previous example (e.g., example 17) or to any other example, further comprising that the second component is a package substrate.

Another example (e.g., example 21) relates to a previous example (e.g., example 17) or to any other example, further comprising that the second component is an interposer.

An example (e.g., example 22) relates to a method for forming an arrangement, comprising providing (510) a first component comprising a surface region with a first plurality of inductive elements for interfacing with a second plurality of inductive elements of a second component, and arranging (520) a filler material on the surface region comprising the first plurality of inductive elements, so that, when the second component is arranged on the filler material, the filler material is arranged between the first and second plurality of inductive elements, wherein the filler material comprises nanoparticles configured to increase a magnetic permeability of the filler material.

Another example (e.g., example 23) relates to a previous example (e.g., example 22) or to any other example, further comprising that the method further comprises arranging (530) the second component on the filler material.

Another example (e.g., example 24) relates to a previous example (e.g., example 23) or to any other example, further comprising that the second component is arranged on the filler material after packaging.

Another example (e.g., example 25) relates to a previous example (e.g., one of the examples 22 to 24) or to any other example, further comprising that the filler material is deposited as droplets on the first component, such that the droplets are spread across the surface region by mechanical pressure exerted by the second component upon mounting of the second component.

An example (e.g., example A1) relates to an arrangement, comprising a first component comprising a surface region with a first plurality of inductive pads for interfacing with a second plurality of inductive pads of a second component, and an interposer arranged on the surface region comprising the first plurality of inductive pads, so that, when the second component is arranged on the interposer, the interposer is arranged between the first and second plurality of inductive pads, wherein the interposer comprises nanoparticles configured to increase a magnetic permeability of a material of the interposer.

Another example (e.g., example A2) relates to a previous example (e.g., example A1) or to any other example, further comprising that the nanoparticles are configured to increase the relative magnetic permeability of the material of the interposer to at least μr=2 at a target frequency.

Another example (e.g., example A3) relates to a previous example (e.g., one of the examples A1 or A2) or to any other example, further comprising that the nanoparticles are configured to increase the relative magnetic permeability of the material of the interposer to at least μr=3 or at least μr=4 at a target frequency.

Another example (e.g., example A4) relates to a previous example (e.g., one of the examples A2 or A3) or to any other example, further comprising that the target frequency is a frequency used for data transmission between the first and second plurality of inductive pads.

Another example (e.g., example A5) relates to a previous example (e.g., one of the examples A2 or A3) or to any other example, further comprising that the target frequency is between 2 GHz and 20 GHz.

Another example (e.g., example A6) relates to a previous example (e.g., one of the examples A1 to A5) or to any other example, further comprising that the interposer has a vertical thickness of between 5 μm and 100 μm.

Another example (e.g., example A7) relates to a previous example (e.g., one of the examples A1 to A6) or to any other example, further comprising that the nanoparticles comprise at least one of yttrium iron garnet (YIG), Cobalt ferrite or Manganese-Zinc ferrite.

Another example (e.g., example A8) relates to a previous example (e.g., one of the examples A1 to A7) or to any other example, further comprising that the interposer is a planar sheet.

Another example (e.g., example A9) relates to a previous example (e.g., one of the examples A1 to A8) or to any other example, further comprising that the interposer comprises a first plurality of regions having a first higher magnetic permeability and at least one second region comprising a second lower magnetic permeability, with the first plurality of regions arranged opposite the first plurality of inductive pads and the at least one second region encircling the respective regions of the first plurality of regions.

Another example (e.g., example A10) relates to a previous example (e.g., one of the examples A1 to A9) or to any other example, further comprising that the interposer comprises an elastomer comprising the nanoparticles.

Another example (e.g., example A11) relates to a previous example (e.g., one of the examples A1 to A10) or to any other example, further comprising that the first component is a semiconductor die, such as a processor die or memory die.

Another example (e.g., example A12) relates to a previous example (e.g., one of the examples A1 to A10) or to any other example, further comprising that the first component is a printed circuit board.

Another example (e.g., example A13) relates to a previous example (e.g., one of the examples A1 to A10) or to any other example, further comprising that the first component is a package substrate.

Another example (e.g., example A14) relates to a previous example (e.g., one of the examples A1 to A13) or to any other example, further comprising that the arrangement further comprises the second component arranged on the interposer.

Another example (e.g., example A15) relates to a previous example (e.g., example A14) or to any other example, further comprising that the second component is a semiconductor die, such as a processor die or memory die.

Another example (e.g., example A16) relates to a previous example (e.g., example A14) or to any other example, further comprising that the second component is a printed circuit board.

Another example (e.g., example A17) relates to a previous example (e.g., example A14) or to any other example, further comprising that the second component is a package substrate.

An example (e.g., example A18) relates to a method for forming an arrangement, comprising providing a first component comprising a surface region with a first plurality of inductive pads for interfacing with a second plurality of inductive pads of a second component, and arranging an interposer on the surface region comprising the first plurality of inductive pads, so that, when the second component is arranged on the interposer, the interposer is arranged between the first and second plurality of inductive pads, wherein the interposer comprises nanoparticles configured to increase a magnetic permeability of a material of the interposer.

Another example (e.g., example A19) relates to a previous example (e.g., example A18) or to any other example, further comprising that the method further comprises arranging the second component on the interposer.

Another example (e.g., example A20) relates to a previous example (e.g., example A19) or to any other example, further comprising that the second component is arranged on the interposer after packaging.

Another example (e.g., example A21) relates to a previous example (e.g., one of the examples A18 to A20) or to any other example, further comprising that the interposer is deposited as droplets on the first component, such that the droplets are spread across the surface region by mechanical pressure exerted by the second component upon mounting of the second component.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps,-functions,-processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An arrangement, comprising:
a first component comprising a surface region with a first plurality of inductive elements for interfacing with a second plurality of inductive elements of a second component; and
a filler material arranged on the surface region comprising the first plurality of inductive elements, so that, when the second component is arranged on the filler material, the filler material is arranged between the first and second plurality of inductive elements, wherein the filler material comprises nanoparticles configured to increase a magnetic permeability of the filler material.

2. The arrangement according to claim 1, wherein the nanoparticles are configured to increase the relative magnetic permeability of the filler material to at least μr=2 at a target frequency.

3. The arrangement according to claim 1, wherein the nanoparticles are configured to increase the relative magnetic permeability of the filler material to at least μr=3 or at least μr=4 at a target frequency.

4. The arrangement according to claim 2, wherein the target frequency is a frequency used for data transmission between the first and second plurality of inductive elements.

5. The arrangement according to claim 2, wherein the target frequency is between 2 GHz and 20 GHz.

6. The arrangement according to claim 1, wherein the filler material has a vertical thickness of between 5 μm and 100 μm.

7. The arrangement according to claim 1, wherein the nanoparticles comprise at least one of yttrium iron garnet (YIG), Iron ferrite, Nickel ferrite, a Z-type hexagonal ferrite, Cobalt ferrite, Manganese-Zinc ferrite, or a Cobalt Iron Boron alloy.

8. The arrangement according to claim 1, wherein the filler material is formed as a planar sheet.

9. The arrangement according to claim 1, wherein the filler material comprises a first plurality of regions having a first magnetic permeability and at least one second region comprising a second magnetic permeability, with the first plurality of regions arranged opposite the first plurality of inductive elements and the at least one second region encircling the respective regions of the first plurality of regions.

10. The arrangement according to claim 9, wherein the first magnetic permeability is greater than the second magnetic permeability.

11. The arrangement according to claim 9, wherein the second magnetic permeability is a complex magnetic permeability having a real part and an imaginary part, and wherein a loss tangent of the second magnetic permeability, defined as the ratio of the imaginary part to the real part, is greater than a loss tangent of the first magnetic permeability.

12. The arrangement according to claim 1, wherein the filler material is an elastomeric filler material.

13. The arrangement according to claim 1, wherein the first component is a semiconductor die.

14. The arrangement according to claim 1, wherein the first component is one of a printed circuit board, a package substrate, or an interposer.

15. The arrangement according to claim 1, wherein the arrangement further comprises the second component arranged on the filler material.

16. The arrangement according to claim 15, wherein the second component is one of a semiconductor die, a printed circuit board, a package substrate, or an interposer.

17. A method for forming an arrangement, comprising:
providing a first component comprising a surface region with a first plurality of inductive elements for interfacing with a second plurality of inductive elements of a second component; and
arranging a filler material on the surface region comprising the first plurality of inductive elements, so that, when the second component is arranged on the filler material, the filler material is arranged between the first and second plurality of inductive elements, wherein the filler material comprises nanoparticles configured to increase a magnetic permeability of the filler material.

18. The method according to claim 17, wherein the method further comprises arranging the second component on the filler material.

19. The method according to claim 17, wherein the second component is arranged on the filler material after packaging.

20. The method according to claim 17, wherein the filler material is deposited as droplets on the first component, such that the droplets are spread across the surface region by mechanical pressure exerted by the second component upon mounting of the second component.
